(19) United States
(12) Patent Application Publication
(10) Pub. No.: US 2022/0416192 A1
(43) Pub. Date: Dec. 29, 2022

(54) DISPLAY PANEL AND MANUFACTURING METHOD THEREOF, AND DISPLAY DEVICE

(71) Applicant: GUANGDONG JUHUA PRINTED DISPLAY TECHNOLOGY CO., LTD., Guangzhou (CN)

(72) Inventors: Yawen Chen, Guangzhou (CN); Wen Shi, Guangzhou (CN); Jinyong Zhuang, Guangzhou (CN); Dong Fu, Guangzhou (CN)

(21) Appl. No.: 17/781,226

(22) PCT Filed: Apr. 1, 2021
(86) PCT No.: PCT/CN2021/084822

§ 371 Date: May 31, 2022

(30) Foreign Application Priority Data
Jun. 2, 2020 (CN) 202010487396.2

(51) Int. Cl. H01L 51/50; H01L 51/56; H01L 27/32

(52) U.S. Cl. CPC H01L 51/5076; H01L 51/56; H01L 27/3211; H01L 51/502; H01L 2251/5369; H01L 27/3244; H01L 2251/558

(57) ABSTRACT

The present disclosure relates to a display panel and a manufacturing method thereof, and a display device. The display panel includes a plurality of pixel units. The pixel unit includes a red sub-pixel, a green sub-pixel and a blue sub-pixel. The red sub-pixel, the green sub-pixel and the blue sub-pixel each include a cathode, an electron transport layer, a quantum dot luminescent layer, a hole function layer and an anode that are stacked. The electron transport layer is made of Mg-doped ZnO nanoparticles, and a Mg doping concentration in the electron transport layer of the red sub-pixel, a Mg doping concentration in the electron transport layer of the green sub-pixel and a Mg doping concentration in the electron transport layer of the blue sub-pixel decrease successively.

### CROSS-REFERENCES TO RELATED APPLICATIONS

This application claims priority to Chinese Patent Application No. 202010487396.2, entitled “DISPLAY PANEL AND PREPARATION METHOD THEREFOR, AND DISPLAY DEVICE” and filed with the Chinese Patent Office on Jun. 2, 2020, the entire contents of which are incorporated herein by reference.

### TECHNICAL FIELD

The present disclosure relates to the field of display technologies, and in particular, to a display panel and a manufacturing method thereof, and a display device.

### BACKGROUND

Semiconductor quantum dots have excellent characteristics of high color purity, high luminous quantum efficiency, adjustable luminous color and a long service life. Such characteristics enable a quantum dot light-emitting diode (QLED) using a quantum dot material as a luminescent layer to have a wide application prospect in fields such as solid-state lighting and flat panel display, which has been widely concerned by academic and industrial circles.

In recent years, the performance of the QLED has been greatly improved through the improvement on a quantum dot material synthesis process and the optimization of a device structure. However, due to a deep energy level and large ionization potential of the quantum dot material, a large hole injection potential barrier exists at an interface between an existing hole transport layer and a quantum dot luminescent layer, which leads to difficult hole injection but easy electron injection, thereby leading to an imbalance in carriers of a QLED luminescent layer, which severely limits the performance of the QLED device. However, an QLED having an inverted structure may use an evaporation-type hole transport layer (HTL) material, which may choose a wider range of material types. Meanwhile, P doping may effectively improve hole mobility, thereby greatly improving the performance of the device. However, in order to save costs and achieve large-area manufacturing, the HTL can only use open mask deposition instead of FMM deposition during the manufacturing of a display panel having an inverted structure. That is, the HTL can only be used as a common layer of RGB, but cannot adopt different thicknesses or p doping concentrations according to different requirements of RGB, so the performance of each color device cannot be effectively optimized independently according to the different requirements of RGB.

### SUMMARY

Various exemplary embodiments of the present disclosure are intended to independently optimize the performance of each color device according to different requirements of RGB.

A display panel, the display panel including: a plurality of pixel units, the pixel unit including a red sub-pixel, a green sub-pixel and a blue sub-pixel, the red sub-pixel, the green sub-pixel and the blue sub-pixel each including a cathode, an electron transport layer, a quantum dot luminescent layer, a hole function layer and an anode that are stacked;

wherein the electron transport layer is made of Mg-doped ZnO nanoparticles, and a Mg doping concentration in the electron transport layer of the red sub-pixel, a Mg doping concentration in the electron transport layer of the green sub-pixel and a Mg doping concentration in the electron transport layer of the blue sub-pixel decrease successively.

The display panel can adjust carrier balance respectively according to different requirements of the red sub-pixel, the green sub-pixel and the blue sub-pixel by successively decreasing the Mg doping concentration in the electron transport layer of the red sub-pixel, the Mg doping concentration in the electron transport layer of the green sub-pixel the Mg doping concentration in the electron transport layer of the blue sub-pixel, to finally achieve optimal carrier balance of the red sub-pixel, the green sub-pixel and the blue sub-pixel at the same time, thereby improving the performance of the display panel.

In one embodiment, the Mg doping concentration in the electron transport layer of the red sub-pixel ranges from 5 wt % to 20 wt %, the Mg doping concentration in the electron transport layer of the green sub-pixel ranges from 2 wt % to 10 wt %, and the Mg doping concentration in the electron transport layer of the blue sub-pixel ranges from 0 wt % to 5 wt %.

In one embodiment, the Mg doping concentration in the electron transport layer of the red sub-pixel ranges from 5 wt % to 10 wt %, and the Mg doping concentration in the electron transport layer of the green sub-pixel ranges from 2.5 wt % to 7.5 wt %.

In one embodiment, a thickness of the electron transport layer of the red sub-pixel, a thickness of the electron transport layer of the green sub-pixel, and a thickness of the electron transport layer of the blue sub-pixel decrease successively.

In one embodiment, a thickness of the electron transport layer of the red sub-pixel ranges from 40 nm to 100 nm, a thickness of the electron transport layer of the green sub-pixel ranges from 30 nm to 80 nm, and a thickness of the electron transport layer of the blue sub-pixel ranges from 20 nm to 60 nm.

In one embodiment, the thickness of the electron transport layer of the red sub-pixel ranges from 40 nm to 70 nm, the thickness of the electron transport layer of the green sub-pixel ranges from 30 nm to 50 nm, and the thickness of the electron transport layer of the blue sub-pixel ranges from 20 nm to 40 nm.

A manufacturing method of a display panel, including the following steps:

providing a substrate, and forming, on the substrate, a cathode, an electron transport layer, a quantum dot luminescent layer, a hole function layer and an anode that are stacked, wherein the step of forming an electron transport layer includes:

depositing ZnO nanoparticles with different Mg doping concentrations on the cathode or the quantum dot luminescent layer by a solution method, to form an electron transport layer of a red sub-pixel, an electron transport layer of a green sub-pixel and an electron transport layer of a blue sub-pixel respectively, wherein a Mg doping concentration in the electron transport layer of the red sub-pixel, a Mg doping concentration in the electron transport layer of the green sub-pixel and a Mg doping concentration in the electron transport layer of the blue sub-pixel decrease successively.

The manufacturing method of a display panel is simple, and can adjust carrier balance respectively according to different requirements of the red sub-pixel, the green sub-pixel and the blue sub-pixel by successively decreasing the Mg doping concentration in the electron transport layer of the red sub-pixel, the Mg doping concentration in the electron transport layer of the green sub-pixel the Mg doping concentration in the electron transport layer of the blue sub-pixel, to finally achieve optimal carrier balance of the red sub-pixel, the green sub-pixel and the blue sub-pixel at the same time, thereby improving the performance of the display panel.

In one embodiment, the solution method is an ink-jet printing process.

In one embodiment, a thickness of the electron transport layer of the red sub-pixel, a thickness of the electron transport layer of the green sub-pixel, and a thickness of the electron transport layer of the blue sub-pixel decrease successively.

A display device, including the display panel described above.

A display device, including a display panel manufactured with the manufacturing method described above.

The display device applied to various exemplary embodiments of the present disclosure includes the display panel described above, and thus can adjust carrier balance respectively according to different requirements of the red sub-pixel, the green sub-pixel and the blue sub-pixel by successively decreasing the Mg doping concentration in the electron transport layer of the red sub-pixel, the Mg doping concentration in the electron transport layer of the green sub-pixel the Mg doping concentration in the electron transport layer of the blue sub-pixel, to finally achieve optimal carrier balance of the red sub-pixel, the green sub-pixel and the blue sub-pixel at the same time, thereby improving the performance of the display panel and the display device.

### BRIEF DESCRIPTION OF THE DRAWINGS

FIG. 1 is a flowchart of a manufacturing method of a display panel according to an implementation of the present disclosure;

FIG. 2 is a schematic diagram of formation of a cathode and a pixel definition layer on a substrate in the manufacturing method of a display panel according to an implementation of the present disclosure;

FIG. 3 is a schematic diagram of formation of an electron transport layer on the cathode in the manufacturing method of a display panel according to an implementation of the present disclosure;

FIG. 4 is a schematic diagram of formation of a quantum dot luminescent layer on the electron transport layer in the manufacturing method of a display panel according to an implementation of the present disclosure; and

FIG. 5 is a schematic structural diagram of a display panel according to an implementation of the present disclosure.

### DETAILED DESCRIPTION OF THE EMBODIMENTS

In order to make the above objectives, features and advantages of the present disclosure more obvious and understandable, specific implementations of the present disclosure are described in detail below with reference to the accompanying drawings. In the following description, many specific details are set forth in order to fully understand the present disclosure. However, the present disclosure can be implemented in many other ways different from those described herein, and those skilled in the art can make similar improvements without departing from the connotation of the present disclosure. Therefore, the present disclosure is not limited by specific embodiments disclosed below.

It is to be noted that, when one element is referred to as “fixed to” another element, it may be directly disposed on the another element or an intermediate element may exist. When one element is considered to be “connected to” another element, it may be directly connected to the another element or an intermediate element may co-exist. The terms “vertical”, “horizontal”, “left”, “right” and similar expressions used herein are for illustrative purposes only.

Unless otherwise defined, all technical and scientific terms used herein have the same meaning as commonly understood by those of ordinary skill in the art to which the present disclosure belongs. The terms used in the specification of the present disclosure are intended only to describe particular embodiments and are not intended to limit the present disclosure. The term “and/or” used herein includes any and all combinations of one or more of the associated listed items.

A manufacturing method of a display panel according to an implementation of the present disclosure includes the following steps:

providing a substrate, and forming, on the substrate, a cathode, an electron transport layer, a quantum dot luminescent layer, a hole function layer and an anode that are stacked, wherein the step of forming an electron transport layer includes:

depositing ZnO nanoparticles with different Mg doping concentrations on the cathode or the quantum dot luminescent layer by a solution method, to form an electron transport layer of a red sub-pixel, an electron transport layer of a green sub-pixel and an electron transport layer of a blue sub-pixel respectively, wherein a Mg doping concentration in the electron transport layer of the red sub-pixel, a Mg doping concentration in the electron transport layer of the green sub-pixel and a Mg doping concentration in the electron transport layer of the blue sub-pixel decrease successively.

The display panel manufactured with the manufacturing method of a display panel according to the present disclosure may be a display panel having a normal structure or a display panel having an inverted structure.

In a manufacturing method of the display panel having a normal structure, the step of forming an electron transport layer includes: depositing ZnO nanoparticles with different Mg doping concentrations on the quantum dot luminescent layer by a solution method, to form an electron transport layer of a red sub-pixel, an electron transport layer of a green sub-pixel and an electron transport layer of a blue sub-pixel respectively, wherein a Mg doping concentration in the electron transport layer of the red sub-pixel, a Mg doping concentration in the electron transport layer of the green sub-pixel and a Mg doping concentration in the electron transport layer of the blue sub-pixel decrease successively.

In a manufacturing method of the display panel having an inverted structure, the step of forming an electron transport layer includes: depositing ZnO nanoparticles with different Mg doping concentrations on the cathode by a solution method, to form an electron transport layer of a red sub-pixel, an electron transport layer of a green sub-pixel and an electron transport layer of a blue sub-pixel respectively, wherein a Mg doping concentration in the electron transport layer of the red sub-pixel, a Mg doping concentration in the electron transport layer of the green sub-pixel and a Mg doping concentration in the electron transport layer of the blue sub-pixel decrease successively.

The display panel obtained with the manufacturing method of a display panel according to the above implementation of the present disclosure includes: a plurality of pixel units, the pixel unit including a red sub-pixel, a green sub-pixel and a blue sub-pixel, the red sub-pixel, the green sub-pixel and the blue sub-pixel each including a cathode, an electron transport layer, a quantum dot luminescent layer, a hole function layer and an anode that are stacked. The quantum dot luminescent layer includes a quantum dot luminescent layer of the red sub-pixel, a quantum dot luminescent layer of the green sub-pixel and a quantum dot luminescent layer of the blue sub-pixel.

In the step of forming, on the substrate, a cathode, an electron transport layer, a quantum dot luminescent layer, a hole function layer and an anode that are stacked, a cathode of the red sub-pixel, a cathode of the green sub-pixel and a cathode of the blue sub-pixel are formed respectively; an electron transport layer of the red sub-pixel, an electron transport layer of the green sub-pixel and an electron transport layer of the blue sub-pixel are formed respectively; a quantum dot luminescent layer of the red sub-pixel, a quantum dot luminescent layer of the green sub-pixel and a quantum dot luminescent layer of the blue sub-pixel are formed respectively; a hole function layer of the red sub-pixel, a hole function layer of the green sub-pixel and a hole function layer of the blue sub-pixel are formed respectively; and an anode of the red sub-pixel, an anode of the green sub-pixel and an anode of the blue sub-pixel are formed respectively.

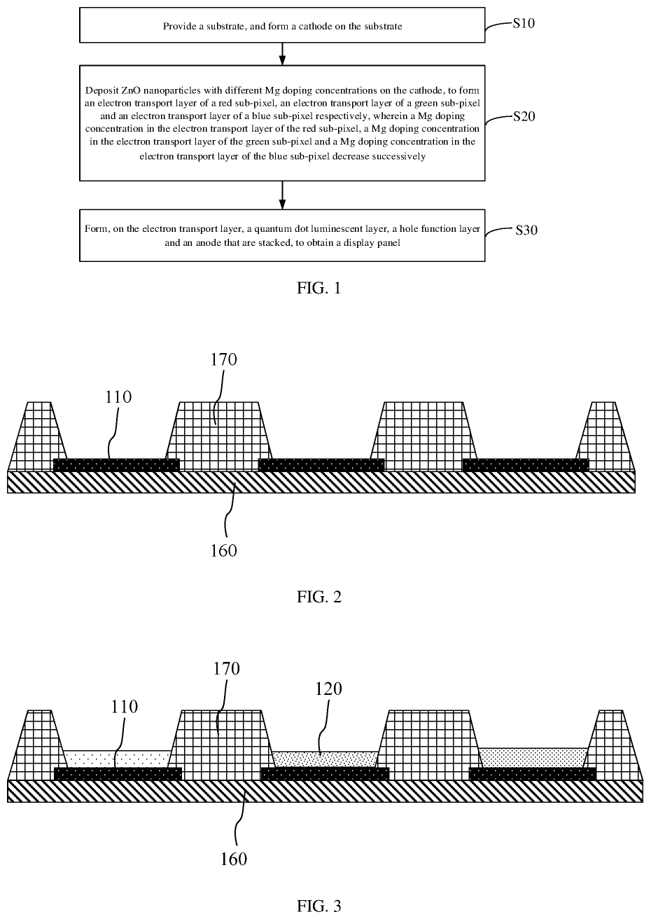

Referring to FIG. 1, a manufacturing method of a display panel according to an implementation of the present disclosure includes the following steps.

In S10, a substrate is provided, and a cathode is formed on the substrate.

A TFT array drive circuit, a patterned cathode 110 and a corresponding pixel definition layer 170 are manufactured on a substrate 160, as shown in FIG. 2.

The substrate 160 includes a substrate and an array drive unit, wherein the substrate may be a rigid or flexible substrate. The rigid substrate may be glass, and the flexible substrate may be PI or the like. The array drive unit is configured to drive an upper electroluminescent pixel unit.

A cathode 110 is a transparent cathode or a reflective cathode. The transparent cathode is made of ITO or ITO/thin metal. The thin metal includes Mg, Ba, Yb, Ag, Al or their alloys or stacked structures, with a thickness ranging from 5 nm to 20 nm. The reflective cathode is an ITO/thick metal layer or a single thick metal layer. Thick metal includes Mg, Ba, Yb, Ag, Al or their alloys or stacked structures, with a thickness ranging from 40 nm to 200 nm. The cathode may be a reflective cathode, that is, a top-emitting display panel, which is conducive to increasing an aperture ratio.

A material surface of the pixel definition layer 170 may be a photophobic material with a thickness of about 1 μm and prepared by a yellow light process. A pixel opening of the pixel definition layer 170 corresponds to a pixel luminescent region of the panel and forms an electrical connection hole with the array drive unit to define luminescent areas and positions of the sub-pixels.

In S20, ZnO nanoparticles with different Mg doping concentrations are deposited on the cathode by a solution method, to form an electron transport layer of a red sub-pixel, an electron transport layer of a green sub-pixel and an electron transport layer of a blue sub-pixel respectively, wherein a Mg doping concentration in the electron transport layer of the red sub-pixel, a Mg doping concentration in the electron transport layer of the green sub-pixel and a Mg doping concentration in the electron transport layer of the blue sub-pixel decrease successively.

In one embodiment, the solution method is an ink-jet printing process. That is, ZnO nanoparticles with different Mg doping concentrations are deposited on the cathode by the ink-jet printing process to form an electron transport layer 120 of the red sub-pixel, an electron transport layer 120 of the green sub-pixel and an electron transport layer 120 of the blue sub-pixel respectively, as shown in FIG. 3.

In one embodiment, the Mg doping concentration in the electron transport layer 120 of the red sub-pixel ranges from 5 wt % to 20 wt %, the Mg doping concentration in the electron transport layer 120 of the green sub-pixel ranges from 2 wt % to 10 wt %, and the Mg doping concentration in the electron transport layer 120 of the blue sub-pixel ranges from 0 wt % to 5 wt %.

In another embodiment, the Mg doping concentration in the electron transport layer 120 of the red sub-pixel ranges from 5 wt % to 10 wt %, and the Mg doping concentration in the electron transport layer 120 of the green sub-pixel ranges from 2.5 wt % to 7.5 wt %.

In one embodiment, a thickness of the electron transport layer 120 of the red sub-pixel, a thickness of the electron transport layer 120 of the green sub-pixel, and a thickness of the electron transport layer 120 of the blue sub-pixel decrease successively. This helps achieve a better optical cavity length structure.

In one embodiment, a thickness of the electron transport layer 120 of the red sub-pixel ranges from 40 nm to 100 nm, a thickness of the electron transport layer 120 of the green sub-pixel ranges from 30 nm to 80 nm, and a thickness of the electron transport layer 120 of the blue sub-pixel ranges from 20 nm to 60 nm.

In another embodiment, the thickness of the electron transport layer 120 of the red sub-pixel ranges from 40 nm to 70 nm, the thickness of the electron transport layer 120 of the green sub-pixel ranges from 30 nm to 50 nm, and the thickness of the electron transport layer 120 of the blue sub-pixel ranges from 20 nm to 40 nm.

Through a combination of ZnO nanoparticles with different Mg doping concentrations as electron transport materials and different ETL thicknesses, carrier balance of luminescent sub-pixels and an optimal optical cavity length of an RGB display panel having an inverted structure can be achieved at the same time, thereby finally improving the performance of the panel.

In S30, a quantum dot luminescent layer, a hole function layer and an anode that are stacked are formed on the electron transport layer, to obtain the display panel.

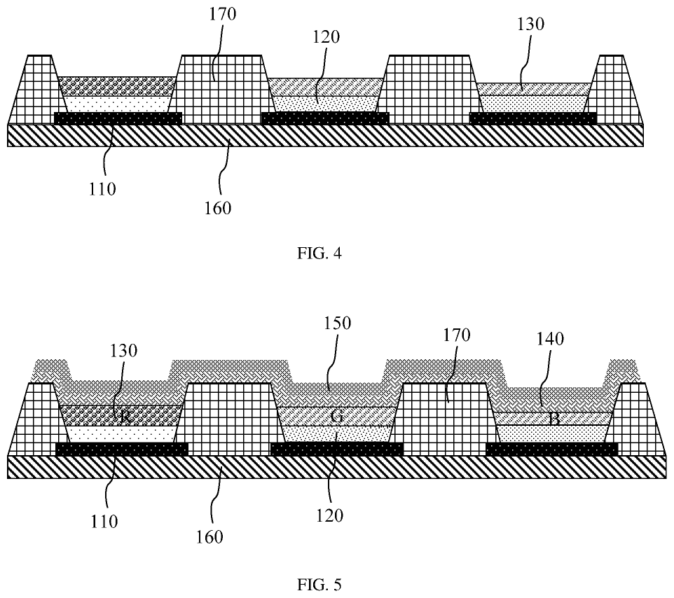

A quantum dot luminescent layer 130 is deposited on the electron transport layer 120 of ZnO nanoparticles with different thicknesses and different Mg doping concentrations, as shown in FIG. 4.

A hole function layer 140 is deposited on a whole surface of the quantum dot luminescent layer 130 by open mask. The hole function layer 140 is a common layer, preventing the use of FMM, which can reduce manufacturing costs and facilitate large-scale production.

An anode 150 is deposited on a whole surface of the hole function layer 140 by open mask, to obtain the display panel shown in FIG. 5. In one embodiment, after deposition of the anode 150, a polarizer layer (CPL) may be further deposited, which is beneficial to improve the light output efficiency. Finally, the whole display panel is packaged.

The manufacturing method of a display panel is simple, and can adjust carrier balance respectively according to different requirements of the red sub-pixel, the green sub-pixel and the blue sub-pixel by successively decreasing the Mg doping concentration in the electron transport layer of the red sub-pixel, the Mg doping concentration in the electron transport layer of the green sub-pixel the Mg doping concentration in the electron transport layer of the blue sub-pixel, to finally achieve optimal carrier balance of the red sub-pixel, the green sub-pixel and the blue sub-pixel at the same time, thereby improving the performance of the display panel.

Referring to FIG. 5, the display panel 100 according to an implementation of the present disclosure includes a plurality of pixel units. The pixel unit includes a red sub-pixel, a green sub-pixel and a blue sub-pixel. The red sub-pixel, the green sub-pixel and the blue sub-pixel each include a cathode 110, an electron transport layer 120, a quantum dot luminescent layer 130, a hole function layer 140 and an anode 150 that are stacked.

In the present disclosure, layout rules of the pixel units and the sub-pixels are not limited. The sub-pixels may be of a structure arranged side by side in a linear manner, or a structure arranged in a triangular manner. In this implementation, in the display panel 100 as shown in FIG. 5, the red sub-pixel, the green sub-pixel and the blue sub-pixel are successively arranged side by side from left to right.

The red sub-pixel, the green sub-pixel and the blue sub-pixel may have an inverted structure or a normal structure. In one implementation, the red sub-pixel, the green sub-pixel and the blue sub-pixel all have an inverted structure. That is, the red sub-pixel, the green sub-pixel and the blue sub-pixel each include, from the bottom up, a cathode 110, an electron transport layer 120, a quantum dot luminescent layer 130, a hole function layer 140 and an anode 150 that are stacked.

The electron transport layer 120 is made of Mg-doped ZnO nanoparticles. A Mg doping concentration in the electron transport layer 120 of the red sub-pixel, a Mg doping concentration in the electron transport layer 120 of the green sub-pixel and a Mg doping concentration in the electron transport layer 120 of the blue sub-pixel decrease successively. That is, according to the characteristics of red light with more electrons and blue light with fewer electrons in RGB devices, an electron current of the red light device is reduced, an electron current of the blue light device is increased, and at the same time, the carrier balance of the RGB devices is realized.

The display panel 100 may further include a substrate 160. The substrate 160 includes a substrate and an array drive unit, wherein the substrate may be a rigid or flexible substrate. The rigid substrate may be glass, and the flexible substrate may be PI or the like. The array drive unit is configured to drive an upper electroluminescent pixel unit.

A cathode 110 is a transparent cathode or a reflective cathode. The transparent cathode is ITO or ITO/thin metal. The thin metal includes Mg, Ba, Yb, Ag, Al or their alloys or stacked structures, with a thickness ranging from 5 nm to 20 nm. The reflective cathode is an ITO/thick metal layer or a single thick metal layer. The thick metal layer includes Mg, Ba, Yb, Ag, Al or their alloys or stacked structures, with a thickness ranging from 40 nm to 200 nm. The cathode may be a reflective cathode, that is, a top-emitting display panel, which is conducive to increasing an aperture ratio. In this implementation, the cathodes 110 are stacked on a surface of the substrate 160.

The display panel 100 may further include a pixel definition layer 170. The pixel definition layer 170 has a pixel opening at a position opposite to the cathode 110. A material surface of the pixel definition layer 170 may be a photophobic material with a thickness of about 1 μm and prepared by a yellow light process. A pixel opening of the pixel definition layer 170 corresponds to a pixel luminescent region of the panel and forms an electrical connection hole with the array drive unit to define luminescent areas and positions of the sub-pixels.

The quantum dot luminescent layer 130 is an II-VI group compound semiconductor and a core-shell structure thereof, such as CdS, CdSe, CdS/ZnS, CdSe/ZnS or CdSe/CdS/ZnS, which may also be III-V or IV-VI group compound semiconductor and a core-shell structure thereof, such as GaAs, InP, PbS/ZnS or PbSe/ZnS, etc.

The hole function layer 140 may be manufactured with a polymer processed by a solution method, including, but not limited to, TFB, PVK, etc. The hole function layer 140, when being a hole transport layer (HTL), may be manufactured with small molecules deposited by an evaporation process to prevent damages to the lower quantum dot luminescent layer 130. Small molecule hole transport materials deposited by evaporation include all common evaporation-type small molecule hole transport materials in the art. In one embodiment, the HTL is a P-type doped HTL, which may effectively improve hole transport performance of the HTL. The doped HTL may be a stacked structure of HTLs/P-doped HTLs to prevent exciton quenching of P-type doping for the quantum dot luminescent layer 130. In one embodiment, an electron barrier layer (EBL) may be further introduced between the HTL and the quantum dot luminescent layer 130, and a hole injection layer (HIL) may be introduced between the HTL and the anode 150, thereby further improving the performance of the device.

The anode 150 is a reflective anode or a transparent anode. The reflective anode is a thick metal layer. The thick metal layer includes, but is not limited to, Ag, Al, Cu or their alloys or stacked structures, with a thickness ranging from 80 nm to 200 nm. The transparent anode is made of IZO or thin metal/IZO. The thin metal includes, but is not limited to, Ag, Al, Cu or their alloys or stacked structures, with a thickness ranging from 5 nm to 18 nm. A cathode of the thin metal may effectively reduce damages to an underlying organic HTL during the deposition of IZO. The anode may be transparent, that is, a top-emitting display panel, which is conducive to increasing an aperture ratio.

The display panel can adjust carrier balance respectively according to different requirements of the red sub-pixel, the green sub-pixel and the blue sub-pixel by successively decreasing the Mg doping concentration in the electron transport layer of the red sub-pixel, the Mg doping concentration in the electron transport layer of the green sub-pixel the Mg doping concentration in the electron transport layer of the blue sub-pixel, to finally achieve optimal carrier balance of the red sub-pixel, the green sub-pixel and the blue sub-pixel at the same time, thereby improving the performance of the display panel.

On the basis of the above implementation, the Mg doping concentration in the electron transport layer 120 of the red sub-pixel ranges from 5 wt % to 20 wt %, the Mg doping concentration in the electron transport layer 120 of the green sub-pixel ranges from 2 wt % to 10 wt %, and the Mg doping concentration in the electron transport layer 120 of the blue sub-pixel ranges from 0 wt % to 5 wt %.

On the basis of the above implementation, the Mg doping concentration in the electron transport layer 120 of the red sub-pixel ranges from 5 wt % to 10 wt %, and the Mg doping concentration in the electron transport layer 120 of the green sub-pixel ranges from 2.5 wt % to 7.5 wt %.

On the basis of the above implementation, a thickness of the electron transport layer 120 of the red sub-pixel, a thickness of the electron transport layer 120 of the green sub-pixel, and a thickness of the electron transport layer 120 of the blue sub-pixel decrease successively. This helps achieve a better optical cavity length structure.

On the basis of the above implementation, a thickness of the electron transport layer 120 of the red sub-pixel ranges from 40 nm to 100 nm, a thickness of the electron transport layer 120 of the green sub-pixel ranges from 30 nm to 80 nm, and a thickness of the electron transport layer 120 of the blue sub-pixel ranges from 20 nm to 60 nm.

On the basis of the above implementation, the thickness of the electron transport layer 120 of the red sub-pixel ranges from 40 nm to 70 nm, the thickness of the electron transport layer 120 of the green sub-pixel ranges from 30 nm to 50 nm, and the thickness of the electron transport layer 120 of the blue sub-pixel ranges from 20 nm to 40 nm.

Through a combination of ZnO nanoparticles with different Mg doping concentrations as electron transport materials and different ETL thicknesses, carrier balance of luminescent sub-pixels and an optimal optical cavity length of an RGB display panel having an inverted structure can be achieved at the same time, thereby finally achieving the optimal performance of the panel.

On the basis of the above implementation, the hole function layer 140 is selected from at least one of a hole transport layer and a hole injection layer. The hole function layer 140 in this implementation is a hole transport layer. Certainly, in other implementations, the hole function layer may also be a hole injection layer, or a stack of a hole transport layer and a hole injection layer.

A display device according to an implementation includes the display panel described above or a display panel manufactured with the manufacturing method described above.

The display device applied to the technical solutions of the present disclosure includes the display panel described above, and thus can adjust carrier balance respectively according to different requirements of the red sub-pixel, the green sub-pixel and the blue sub-pixel by successively decreasing the Mg doping concentration in the electron transport layer of the red sub-pixel, the Mg doping concentration in the electron transport layer of the green sub-pixel the Mg doping concentration in the electron transport layer of the blue sub-pixel, to finally achieve optimal carrier balance of the red sub-pixel, the green sub-pixel and the blue sub-pixel at the same time, thereby improving the performance of the display panel and the display device.

The following are specific embodiments.

### Embodiment 1

A substrate is provided, and a cathode is formed on the substrate. The cathode is made of ITO.

ZnO nanoparticles with different Mg doping concentrations are deposited on the cathode by a solution method to form an electron transport layer of a red sub-pixel, an electron transport layer of a green sub-pixel and an electron transport layer of a blue sub-pixel respectively. A Mg doping concentration in the electron transport layer of the red sub-pixel, a Mg doping concentration in the electron transport layer of the green sub-pixel and a Mg doping concentration in the electron transport layer of the blue sub-pixel are 20%, 10% and 5% respectively. Thicknesses of the electron transport layer of the red sub-pixel, the electron transport layer of the green sub-pixel and the electron transport layer of the blue sub-pixel are 30 nm, 30 nm and 30 nm respectively.

A quantum dot luminescent layer is formed on the electron transport layer. A red quantum dot luminescent layer, a green quantum dot luminescent layer and a blue quantum dot luminescent layer are made of CdS/ZnS, CdSe/ZnS and CdS/ZnS respectively.

A hole transport layer is formed on the quantum dot luminescent layer. The hole transport layer is made of NPB.

An anode is evaporated on the hole transport layer, to obtain the display panel. The anode is Ag.

### Embodiment 2

A substrate is provided, and a cathode is formed on the substrate. The cathode is made of ITO.

ZnO nanoparticles with different Mg doping concentrations are deposited on the cathode by a solution method to form an electron transport layer of a red sub-pixel, an electron transport layer of a green sub-pixel and an electron transport layer of a blue sub-pixel respectively. A Mg doping concentration in the electron transport layer of the red sub-pixel, a Mg doping concentration in the electron transport layer of the green sub-pixel and a Mg doping concentration in the electron transport layer of the blue sub-pixel are 20%, 10% and 5% respectively. Thicknesses of the electron transport layer of the red sub-pixel, the electron transport layer of the green sub-pixel and the electron transport layer of the blue sub-pixel are 40 nm, 30 nm and 20 nm respectively.

A quantum dot luminescent layer is formed on the electron transport layer. A red quantum dot luminescent layer, a green quantum dot luminescent layer and a blue quantum dot luminescent layer are made of CdS/ZnS, CdSe/ZnS and CdS/ZnS respectively.

A hole transport layer is formed on the quantum dot luminescent layer. The hole transport layer is made of NPB.

An anode is evaporated on the hole transport layer, to obtain the display panel. The anode is Ag.

### Embodiment 3

A substrate is provided, and a cathode is formed on the substrate. The cathode is made of ITO.

ZnO nanoparticles with different Mg doping concentrations are deposited on the cathode by a solution method to form an electron transport layer of a red sub-pixel, an electron transport layer of a green sub-pixel and an electron transport layer of a blue sub-pixel respectively. A Mg doping concentration in the electron transport layer of the red sub-pixel, a Mg doping concentration in the electron transport layer of the green sub-pixel and a Mg doping concentration in the electron transport layer of the blue sub-pixel are 10%, 5% and 2% respectively. Thicknesses of the electron transport layer of the red sub-pixel, the electron transport layer of the green sub-pixel and the electron transport layer of the blue sub-pixel are 60 nm, 40 nm and 30 nm respectively.

A quantum dot luminescent layer is formed on the electron transport layer. A red quantum dot luminescent layer, a green quantum dot luminescent layer and a blue quantum dot luminescent layer are made of CdS/ZnS, CdSe/ZnS and CdS/ZnS respectively.

A hole transport layer is formed on the quantum dot luminescent layer. The hole transport layer is made of NPB.

An anode is evaporated on the hole transport layer. The anode is Ag.

A polarizer layer (CPL) is deposited on the anode, to obtain the display panel.

### Embodiment 4

A substrate is provided, and a cathode is formed on the substrate. The cathode is made of ITO.

ZnO nanoparticles with different Mg doping concentrations are deposited on the cathode by a solution method to form an electron transport layer of a red sub-pixel, an electron transport layer of a green sub-pixel and an electron transport layer of a blue sub-pixel respectively. A Mg doping concentration in the electron transport layer of the red sub-pixel, a Mg doping concentration in the electron transport layer of the green sub-pixel and a Mg doping concentration in the electron transport layer of the blue sub-pixel are 5%, 2.5% and 0% respectively. Thicknesses of the electron transport layer of the red sub-pixel, the electron transport layer of the green sub-pixel and the electron transport layer of the blue sub-pixel are 50 nm, 40 nm and 30 nm respectively.

A quantum dot luminescent layer is formed on the electron transport layer. A red quantum dot luminescent layer, a green quantum dot luminescent layer and a blue quantum dot luminescent layer are made of CdS/ZnS, CdSe/ZnS and CdS/ZnS respectively.

A hole transport layer is formed on the quantum dot luminescent layer. The hole transport layer is made of NPB.

A hole injection layer is formed on the quantum dot luminescent layer. The hole injection layer is made of MoOx.

An anode is evaporated on the hole transport layer. The anode is Ag.

A polarizer layer (CPL) is deposited on the anode, to obtain the display panel.

### Embodiment 5

A substrate is provided, and an anode is formed on the substrate. The anode is made of ITO.

A hole transport layer is formed on the anode. The hole transport layer is made of NPB.

A quantum dot luminescent layer is formed on the hole transport layer. A red quantum dot luminescent layer, a green quantum dot luminescent layer and a blue quantum dot luminescent layer are made of CdS/ZnS, CdSe/ZnS and CdS/ZnS respectively.

ZnO nanoparticles with different Mg doping concentrations are deposited on the quantum dot luminescent layer by a solution method to form an electron transport layer of a red sub-pixel, an electron transport layer of a green sub-pixel and an electron transport layer of a blue sub-pixel respectively. A Mg doping concentration in the electron transport layer of the red sub-pixel, a Mg doping concentration in the electron transport layer of the green sub-pixel and a Mg doping concentration in the electron transport layer of the blue sub-pixel are 20%, 10% and 5% respectively. Thicknesses of the electron transport layer of the red sub-pixel, the electron transport layer of the green sub-pixel and the electron transport layer of the blue sub-pixel are 30 nm, 30 nm and 30 nm respectively.

A cathode is evaporated on the electron transport layer, to obtain the display panel. The cathode is Ag.

The technical features in the above embodiments may be randomly combined. For concise description, not all possible combinations of the technical features in the above embodiments are described. However, all the combinations of the technical features are to be considered as falling within the scope described in this specification provided that they do not conflict with each other.

The above embodiments only describe several implementations of the present disclosure, and their description is specific and detailed, but cannot therefore be understood as a limitation on the patent scope of the invention. It should be noted that those of ordinary skill in the art may further make variations and improvements without departing from the conception of the present disclosure, and these all fall within the protection scope of the present disclosure. Therefore, the patent protection scope of the present disclosure should be subject to the appended claims.

1. A display panel, comprising:
a plurality of pixel units, each of the plurality of pixel units comprising a red sub-pixel, a green sub-pixel and a blue sub-pixel, the red sub-pixel, the green sub-pixel and the blue sub-pixel each comprising a cathode, an electron transport layer, a quantum dot luminescent layer, a hole function layer, and an anode that are stacked;
wherein the electron transport layer is made of Mg-doped ZnO nanoparticles, and a Mg doping concentration in the electron transport layer of the red sub-pixel, a Mg doping concentration in the electron transport layer of the green sub-pixel and a Mg doping concentration in the electron transport layer of the blue sub-pixel decrease successively.

2. The display panel according to claim 1, wherein the Mg doping concentration in the electron transport layer of the red sub-pixel ranges from 5 wt % to 20 wt %, the Mg doping concentration in the electron transport layer of the green sub-pixel ranges from 2 wt % to 10 wt %, and the Mg doping concentration in the electron transport layer of the blue sub-pixel ranges from 0 wt % to 5 wt %.

3. The display panel according to claim 2, wherein the Mg doping concentration in the electron transport layer of the red sub-pixel ranges from 5 wt % to 10 wt %, and the Mg doping concentration in the electron transport layer of the green sub-pixel ranges from 2.5 wt % to 7.5 wt %.

4. The display panel according to claim 1, wherein the Mg doping concentration in the electron transport layer of the red sub-pixel ranges from 5 wt % to 10 wt %, and the Mg doping concentration in the electron transport layer of the green sub-pixel ranges from 2.5 wt % to 7.5 wt %.

5. The display panel according to claim 1, wherein a thickness of the electron transport layer of the red sub-pixel, a thickness of the electron transport layer of the green sub-pixel, and a thickness of the electron transport layer of the blue sub-pixel decrease successively.

6. The display panel according to claim 1, wherein a thickness of the electron transport layer of the red sub-pixel ranges from 40 nm to 100 nm, a thickness of the electron transport layer of the green sub-pixel ranges from 30 nm to 80 nm, and a thickness of the electron transport layer of the blue sub-pixel ranges from 20 nm to 60 nm.

7. The display panel according to claim 6, wherein the thickness of the electron transport layer of the red sub-pixel ranges from 40 nm to 70 nm, the thickness of the electron transport layer of the green sub-pixel ranges from 30 nm to 50 nm, and the thickness of the electron transport layer of the blue sub-pixel ranges from 20 nm to 40 nm.

8. A manufacturing method of a display panel, the manufacturing method comprising:
providing a substrate; and
forming, on the substrate, a cathode, an electron transport layer, a quantum dot luminescent layer, a hole function layer and an anode that are stacked, wherein forming an electron transport layer comprises:
depositing ZnO nanoparticles with different Mg doping concentrations on the cathode or the quantum dot luminescent layer by a solution method, to form an electron transport layer of a red sub-pixel, an electron transport layer of a green sub-pixel and an electron transport layer of a blue sub-pixel respectively, wherein a Mg doping concentration in the electron transport layer of the red sub-pixel, a Mg doping concentration in the electron transport layer of the green sub-pixel and a Mg doping concentration in the electron transport layer of the blue sub-pixel decrease successively.

9. The manufacturing method of the display panel according to claim 8, wherein the solution method is an ink-jet printing process.

10. The manufacturing method of the display panel according to claim 8, wherein a thickness of the electron transport layer of the red sub-pixel, a thickness of the electron transport layer of the green sub-pixel, and a thickness of the electron transport layer of the blue sub-pixel decrease successively.

11. A display device, comprising:
a display panel, the display panel comprising:
a plurality of pixel units, the pixel unit comprising a red sub-pixel, a green sub-pixel and a blue sub-pixel, the red sub-pixel, the green sub-pixel and the blue sub-pixel each comprising a cathode, an electron transport layer, a quantum dot luminescent layer, a hole function layer and an anode that are stacked;
wherein the electron transport layer is made of Mg-doped ZnO nanoparticles, and a Mg doping concentration in the electron transport layer of the red sub-pixel, a Mg doping concentration in the electron transport layer of the green sub-pixel and a Mg doping concentration in the electron transport layer of the blue sub-pixel decrease successively.

12. The display device according to claim 11, wherein the Mg doping concentration in the electron transport layer of the red sub-pixel ranges from 5 wt % to 20 wt %, the Mg doping concentration in the electron transport layer of the green sub-pixel ranges from 2 wt % to 10 wt %, and the Mg doping concentration in the electron transport layer of the blue sub-pixel ranges from 0 wt % to 5 wt %.

13. The display device according to claim 12, wherein the Mg doping concentration in the electron transport layer of the red sub-pixel ranges from 5 wt % to 10 wt %, and the Mg doping concentration in the electron transport layer of the green sub-pixel ranges from 2.5 wt % to 7.5 wt %.

14. The display device according to claim 11, wherein the Mg doping concentration in the electron transport layer of the red sub-pixel ranges from 5 wt % to 10 wt %, and the Mg doping concentration in the electron transport layer of the green sub-pixel ranges from 2.5 wt % to 7.5 wt %.

15. The display device according to claim 11, wherein a thickness of the electron transport layer of the red sub-pixel, a thickness of the electron transport layer of the green sub-pixel, and a thickness of the electron transport layer of the blue sub-pixel decrease successively.

16. The display device according to claim 11, wherein a thickness of the electron transport layer of the red sub-pixel ranges from 40 nm to 100 nm, a thickness of the electron transport layer of the green sub-pixel ranges from 30 nm to 80 nm, and a thickness of the electron transport layer of the blue sub-pixel ranges from 20 nm to 60 nm.

17. The display device according to claim 16, wherein the thickness of the electron transport layer of the red sub-pixel ranges from 40 nm to 70 nm, the thickness of the electron transport layer of the green sub-pixel ranges from 30 nm to 50 nm, and the thickness of the electron transport layer of the blue sub-pixel ranges from 20 nm to 40 nm.
